(19) United States
(12) Patent Application Publication
(10) Pub. No.: US 2016/0284915 A1
(43) Pub. Date: Sep. 29, 2016

(54) PHOTOVOLTAIC CELL WITH SILICON HETEROJUNCTION

(71) Applicant: COMMISSARIAT A L'ENERGIE ATOMIQUE ET AUX ENERGIES ALTERNATIVES, Paris (FR)

(72) Inventors: Julien Buckley, Grenoble (FR); Matthew Charles, Grenoble (FR)

(73) Assignee: COMMISSARIAT A L'ENERGIE ATOMIQUE ET AUX ENERGIES ALTERNATIVES, Paris (FR)

(21) Appl. No.: 15/032,902

(22) PCT Filed: Nov. 12, 2014
(86) PCT No.: PCT/EP2014/074325

§ 371 Date: Apr. 28, 2016

(30) Foreign Application Priority Data
Nov. 12, 2013 (FR) 1361023

(51) Int. Cl. H01L 31/074; H01L 31/0224; H01L 31/18; H01L 31/0236

(52) U.S. Cl. CPC H01L 31/074; H01L 31/02366; H01L 31/022466; H01L 31/1856; H01L 31/1804; H01L 31/1884

(57) ABSTRACT

The invention relates to a photovoltaic cell with silicon heterojunction comprising a doped crystalline silicon substrate, in which: —a first face of the substrate is successively covered with a passivation layer, an amorphous or p or p+ doped microcrystalline silicon layer and a layer of a transparent conducting material, —the second face of the substrate is successively covered with an amorphous or n or n+ doped microcrystalline silicon layer and a layer of a transparent conducting material. Between the substrate and the amorphous or n or n+ doped microcrystalline silicon layer, the cell comprises a layer of a crystalline semi-conducting material selected from gallium nitride or indium gallium nitride and having a conduction band that is sensitively aligned with the conduction band of the silicon and a band gap greater than that of silicon, in such a way as to promote an electron current while limiting a hole current in the substrate towards the amorphous or n or n+ doped microcrystalline silicon layer.

### FIELD OF THE INVENTION

The present invention relates to a photovoltaic cell with a silicon heterojunction and to a method for manufacturing such a cell.

### BACKGROUND OF THE INVENTION

In a solar cell with a silicon heterojunction (often designated with the acronym SHJ for “Silicon HeteroJunction solar cell”), the internal electric field indispensable for the photovoltaic effect is generated by a p− or p+-doped hydrogenated amorphous silicon layer (conventionally noted as a-Si:H(p)) deposited on a substrate of n-doped silicon crystal substrate (conventionally noted as c-Si(n)), unlike a conventional homojunction structure in which the internal electric field is obtained by a p-doped silicon crystal/n-doped silicon crystal junction.

Conversely, there also exist cells with a silicon heterojunction in which the silicon crystal substrate is p-doped and the hydrogenated amorphous silicon layer is n− or n+-doped.

The making of the heterojunction from amorphous silicon, which may be deposited at a low temperature, gives the possibility of minimizing the thermal budget imposed to the silicon crystal substrate and thus avoids degradation of its properties.

The doped layer of the type opposite to that of the substrate forms the emitter of the photovoltaic cell.

On the other face of the substrate, a doped amorphous or microcrystalline silicon layer of the same type as that of the substrate forms a repulsive electric field. If said layer is located on the rear face of the substrate, i.e. the face opposite to the front face intended to receive the solar radiation, it is designated by the term of “Back Surface Field” (BSF); if it is found on the front face, this is referred to as “Front Surface Field” (FSF).

This layer has the function of driving away the minority carriers of the substrate (i.e. electrons if the substrate is p-doped, and holes if the substrate is n-doped), with view to avoiding recombination with the contacts formed on the face of the cell opposite to the emitter.

The absorption of a photon by the cell is expressed by the generation of an electron/hole pair which, under the effect of the intrinsic electric field generated by the heterojunction, dissociates so that the photo-generated minority carriers are directed towards the region wherein these carriers are in majority.

Thus, in a substrate of the p type, the photo-generated electrons are directed towards the emitter of the n+ type while the holes are directed towards the p+-type repulsive field layer; in a substrate of type n, the photo-generated holes are directed towards the p+ type emitter while the electrons are directed towards the n+ type repulsive field layer.

Electric contacts are formed on the front face and on the rear face of the cell in order to collect said photo-generated carriers.

In order to avoid recombinations at the interfaces and to increase the conversion efficiency, inserting a passivation layer is known, for example in intrinsic hydrogenated amorphous silicon (conventionally noted as a-Si:H(i)), between the substrate and each layer of doped amorphous silicon, so as to benefit from excellent a-Si:H(i)/c-Si(n or p) interface properties and to increase the open circuit voltage (Voc) of the cell.

The low concentration of recombinant traps at the interfaces is explained by the absence of doping impurities in the a-Si:H(i) layer.

FIG. 1 is a perspective view illustrating the principle of a photovoltaic cell with a heterojunction in which the substrate 1 is of the n type.

Although this is not illustrated here, both faces of the substrate are generally textured so as to minimize reflection phenomena.

The front face of the cell, intended to receive the solar radiation is designated by the marking F, the rear face, opposite to the front face, is designated with the marking B.

The heterojunction is formed by a layer 3 of amorphous silicon of the p+-type doped located on the front face of the substrate.

Between said layer 3 and the substrate 1 is inserted a passivation layer 2 in intrinsic amorphous silicon.

The rear face of the substrate 1 is as for it covered with a passivation layer 4 in intrinsic amorphous silicon and with an n+-doped amorphous silicon layer 5.

Each of the two layers 3, 5 of doped amorphous silicon, is covered with a layer 6, 7 of a transparent conductive material.

Finally, electric contacts 8, 9 are respectively formed on the front face and on the rear face of the cell.

The article of Kinoshita et al. shows different solutions for improving the efficiency of a photovoltaic cell with a heterojunction [Kinoshita11].

The authors of this article for this purpose are interested in the optimization of the amorphous silicon layers and of the transparent conductive material, in the optimization of the electric contacts and in the improvement of optical confinement.

However, recombinations subsist in such a cell, which reduce the yield of the latter.

An object of the invention is therefore to design a photovoltaic cell in which such recombinations are minimized, or even suppressed.

### SHORT DESCRIPTION OF THE INVENTION

In order to find a remedy to the aforementioned drawbacks, a photovoltaic cell with a silicon heterojunction is proposed, comprising a n- or p-type doped silicon crystal substrate, wherein:
a first main face of the substrate is successively covered with a passivation layer, with a p− or p+-type doped amorphous or microcrystalline silicon layer and with a layer of a transparent conductive material,
the second main face of the substrate is successively covered with an n− or n+-type doped amorphous or microcrystalline silicon layer and with a layer of a transparent conductive material.

According to the invention, said cell comprises, between the substrate and n− or n+-type doped amorphous or microcrystalline silicon layer, a layer of a crystalline semi-conducting material having a conduction band substantially aligned with the conduction band of the silicon and a forbidden band greater than that of silicon, so that said layer promotes a current of electrons while limiting a current of holes from the substrate to the n− or n+-type doped amorphous or microcrystalline silicon layer. Said crystalline semi-conducting material inserted between the substrate and the n− or n+-type doped amorphous or microcrystalline silicon is selected from gallium nitride and from gallium and indium nitride.

By “substantially aligned conduction bands” is meant a difference between the conduction bands of both materials of less than 0.1 eV in absolute value.

In the present text, the term of “successively” designates an order for stacking various layers relatively to a main face of the substrate, but does not necessarily imply that two successive layers are in direct contact, i.e. that they have a common interface.

By “transparent conductive material” is meant an electrically conductive material transparent to solar radiation.

By “intrinsic silicon”, is meant silicon not containing any dopant or at the very least that no dopant has been intentionally introduced during the formation of the material. In any case, it is considered that the silicon is intrinsic if its concentration of active dopants is less than 10¹⁵/cm³.

For this purpose, the deposition of intrinsic silicon in an amorphous or crystalline form is carried out in a chamber not contaminated with dopant impurities.

By “doped silicon” (n or p), is meant silicon for which the concentration of active dopants is greater than 10¹⁵/cm³.

By “strongly doped silicon” (n+ or p+), is meant silicon for which the concentration of active dopants is greater than 10¹⁸/cm³.

In a particular advantageous way, the second main face of the substrate has a texture revealing the planes (111) of the silicon.

According to an embodiment, the thickness of the layer of said crystalline semi-conducting material is comprised between 0.5 nm and 50 nm, preferably between 1 nm and 10 nm.

Another object relates to a method for manufacturing a photovoltaic cell with a silicon heterojunction as described above.

According to this method:
are successively formed, on a first main face of a n- or p-doped silicon crystal substrate, a passivation layer, a p− or p+-type doped amorphous or microcrystalline silicon layer, a layer of a transparent conductive material and a first collector of carriers,
are successively formed, on the second main face of the substrate, a n− or n+-type doped amorphous or microcrystalline silicon layer, a layer of a transparent conductive material and a second collector of carriers,
before forming said n− or n+-type doped amorphous or microcrystalline silicon layer, a layer of a semi-conducting material is formed by epitaxy on the substrate, having a conduction band substantially aligned with the conduction band of silicon and a forbidden band greater than that of silicon. Said crystalline semi-conducting material is gallium nitride or gallium and indium nitride.

The second face of the substrate is advantageously textured before the epitaxy step so as to form pyramids revealing the planes (111) of the silicon.

According to an embodiment, the crystalline semi-conducting material is gallium nitride and the gallium nitride layer is formed by epitaxy with a molecular beam (MBE) or by epitaxy in a vapor phase with organometallic compounds (MOVPE).

The epitaxy temperature of said gallium nitride layer is advantageously comprised between 600 and 800° C.

The thickness of the semi-conducting crystalline material layer is comprised between 0.5 nm and 50 nm, preferably between 1 nm and 10 nm.

### SHORT DESCRIPTION OF THE DRAWINGS

Other features and advantages of the invention will emerge from the detailed description which follows, with reference to the appended drawings wherein:

FIG. 1 is a perspective block diagram of a photovoltaic cell with a silicon heterojunction,

FIG. 2A illustrates the band diagram of a photovoltaic cell with a conventional heterojunction, comprising a substrate of type n,

FIG. 2B illustrates the band diagram of a photovoltaic cell with a conventional heterojunction, comprising a substrate of type p,

FIG. 3A is a sectional view of a photovoltaic cell with a heterojunction according to the invention, comprising a substrate of type n,

FIG. 3B illustrates the band diagram of a photovoltaic cell with a heterojunction according to the invention, comprising a substrate of type p,

FIG. 4A is a sectional view of a photovoltaic cell with a heterojunction according to the invention, comprising a substrate of type n,

FIG. 4B illustrates the band diagram of a photovoltaic cell with a heterojunction according to the invention, comprising a substrate of type p,

FIG. 5 illustrates the positions of the valence and conduction bands of the silicon and of an indium and gallium nitride for different indium contents,

FIG. 6 illustrates a structure on which numerical simulations were carried out in order to show the effect of the crystalline semi-conducting material layer according to the invention,

FIGS. 7A and 7B respectively illustrate the band diagrams of the first simulated structure, at the anode and at the cathode; FIGS. 7C and 7D respectively illustrate the band diagrams of the second simulated structure, at the anode and at the cathode,

FIG. 8 shows the variation of the cathode current according to the bias at the anode for the first structure (curve a) and for the second structure (curve b),

FIG. 9A shows the variation of the hole current at the anode according to the bias at the anode for the first structure (curve a) and for the second structure (curve b),

FIG. 9B shows the variation of the hole current at the cathode depending on the bias at the anode for the first structure (curve a) and for the second structure (curve b).

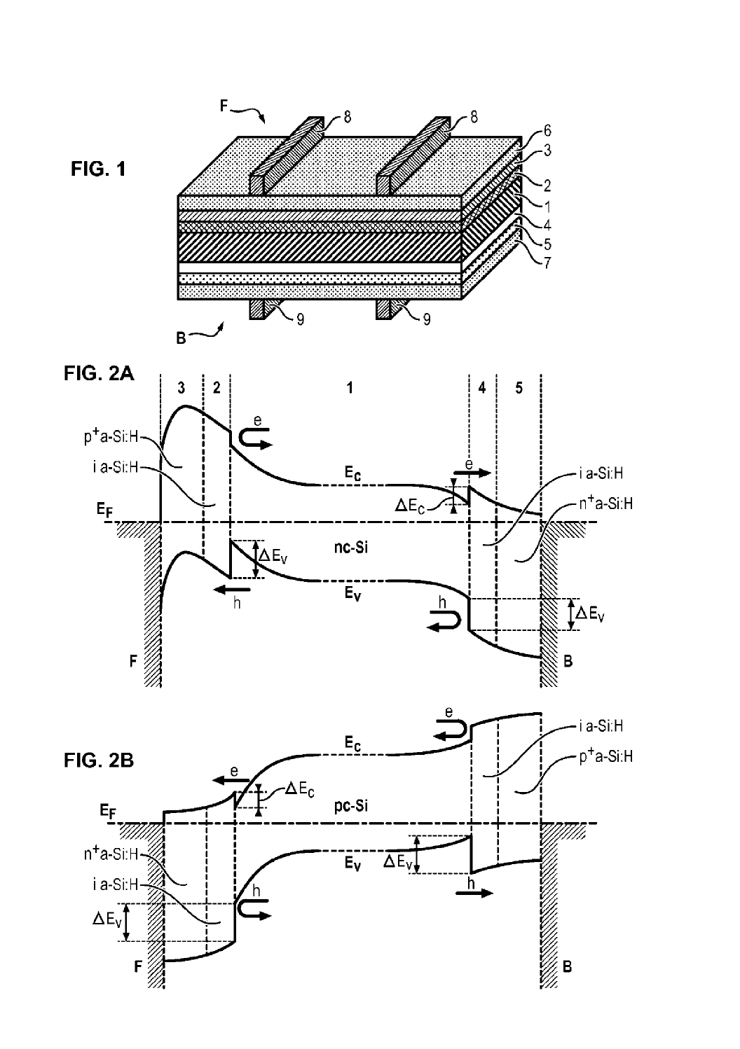

### DETAILED DESCRIPTION OF THE INVENTION

In order to find a remedy to the existence of recombinations in photovoltaic cells with a heterojunction, the inventors analyzed, from band diagrams of these cells, the causes of these recombinations.

FIGS. 2A and 2B respectively show the band diagram of a conventional cell with a silicon heterojunction for which the substrate is n-doped and that of a conventional silicon heterojunction cell for which the substrate is p-doped.

These diagrams stem from [Hekmatshoar11].

It will be noted that the layers of transparent conductive material on the front face and on the rear face are not illustrated on these diagrams, which are only valid for a short-circuited cell.

The conduction band and the valence band are respectively designated by the references E_{C} and E_{V}, the line E_{F} referring to the Fermi level.

The electrons are designated by the marking e, the holes by the marking h.

As this may be seen on the diagram of FIG. 2A, there exists, at the interface between the substrate 1 and the passivation layer 4 located on the side of the n+ repulsive field layer, a shift ΔEc between the conduction band of the substrate 1 of type n and that of the passivation layer 4 in intrinsic amorphous silicon.

This shift in the conduction bands, which forms a barrier to the passage of photogenerated electrons towards the rear contact 9, is of the order of 0.1 eV.

Moreover, at this same interface, there exists a shift ΔEv between the valence band of the substrate 1 of type n and that of the intrinsic amorphous silicon layer 4.

This shift in the valence bands, which forms a barrier to the passage of holes from the emitter to the rear contact 9, is of the order of 0.4 eV.

In such a cell, recombinations occur on either side of the interface between the substrate 1 and the passivation layer 4.

Indeed, in the substrate 1, the photogenerated electrons which do not manage to cross the barrier ΔEc recombine with the holes from the emitter which do not cross the barrier ΔEv.

On the other hand, in the rear contact 9, the photogenerated electrons which cross the barrier ΔEc recombine with the holes from the emitter which cross the barrier ΔEv.

These recombinations are a penalty for the yield of the photovoltaic cell.

In the case of a substrate of type p (cf. diagram of FIG. 2B), there exists, at the interface between the substrate and the passivation layer located on the side of the n+ emitter, a shift ΔEc between the conduction band of the substrate of type p and that of the intrinsic amorphous silicon layer.

This shifting in the conduction bands, which forms a barrier to the passage of photogenerated electrons towards the emitter, is of the order of 0.1 eV.

Moreover, at this same interface, there exists a shift ΔEv between the valence band of the substrate of type n and that of the intrinsic amorphous silicon layer.

This shifting in the valence bands, which forms a barrier to the passage of the holes from the rear contact to the emitter, is of the order of 0.4 eV.

In such a cell, recombinations occur on either side of the interface between the substrate and the passivation layer.

Indeed, in the substrate, the photogenerated electrons which do not manage to cross the barrier ΔEc recombine with the holes from the rear contact which do not cross the barrier ΔEv.

In the emitter, the photogenerated electrons which cross the barrier ΔEc recombine with the holes from the rear contact which cross the barrier ΔEv.

Like in the situation of FIG. 2A, these recombinations are a penalty for the yield of the photovoltaic cell.

The inventors determined that a layer may be inserted between the substrate and the amorphous silicon layer of type n or n+ so as to limit the recombinations described above.

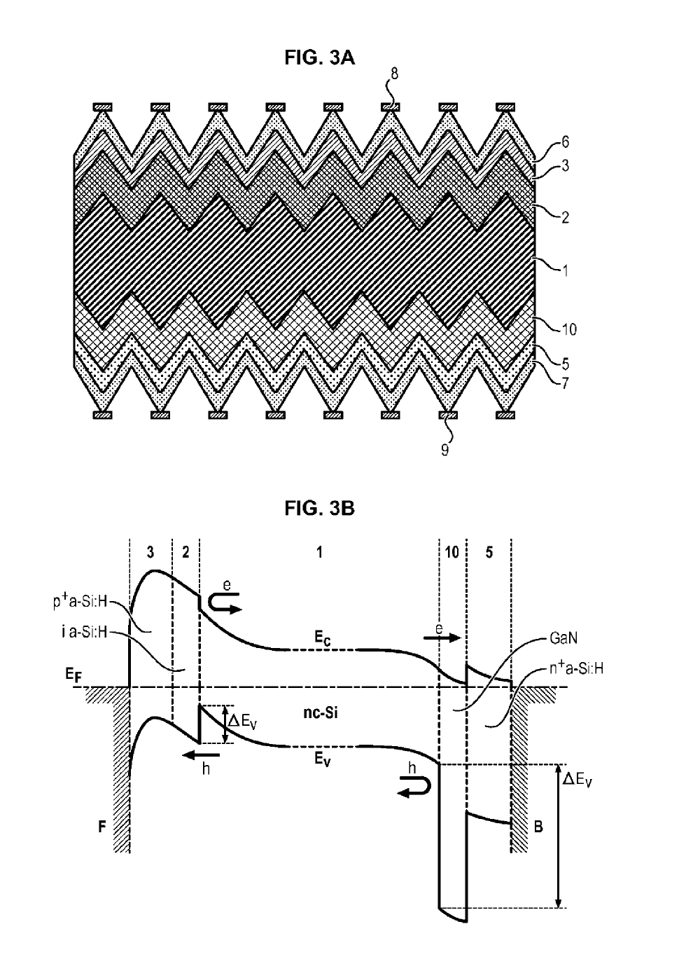

FIG. 3A is a sectional view of a photovoltaic cell of the invention according to an embodiment of the invention, wherein the substrate is of type n.

It is considered in this embodiment that the heterojunction is laid out on the front face of the cell, but it is obvious that the invention also applies to a heterojunction placed on the rear face of the cell.

A first main face of the substrate 1 is successively covered with a passivation layer 2, with a p− or p+-type doped amorphous or microcrystalline silicon layer 3 and with a layer 6 of a transparent conductive material.

Therefore, the heterojunction is made on the side of the first face.

The second main face of the substrate, opposite to the first, is successively covered with an n− or n+-doped microcrystalline or amorphous silicon layer 5 and with a layer 7 of a transparent conductive material.

A repulsive field is therefore formed by the layer 5 which is doped with the same type of dopant as the substrate.

The cell further comprises on the second face, between the substrate 1 and the n− or n+-type doped amorphous or microcrystalline silicon layer 5, a layer 10 of a crystalline semi-conducting material having a conduction band substantially aligned with the conduction band of silicon and a forbidden band greater than that of silicon.

In a particularly advantageous way, the material of the layer 10 is gallium nitride.

As illustrated in FIG. 5, which illustrates the positions of the valence and conduction bands of silicon and of an indium and gallium nitride for different indium contents [Ager09], the GaN has a conduction band substantially aligned with that of silicon.

Moreover, GaN has a forbidden band of 3.4 eV, which is clearly greater than that of silicon, which is of the order of 1.1 eV.

The effect of this GaN layer 10 is illustrated in FIG. 3B, which illustrates the band diagram of a photovoltaic cell with a heterojunction as schematized in FIG. 3A.

At the interface between the silicon substrate 1 of type n and the GaN layer 10, the shift ΔEc of the conduction bands is zero since the conduction bands of both of these materials are substantially aligned.

On the other hand, because of the greater forbidden band of GaN, the shift ΔEv of the valence bands is greater than in the absence of the GaN layer (FIG. 2A) and is of the order of 2.3 eV.

The result of this layout of bands is that the photogenerated electrons no longer encounter any barrier opposing their passage towards the n− or n+-doped amorphous or microcrystalline silicon layer 5.

On the other hand, the holes encounter a substantial barrier which opposes their passage towards the layer 5.

In other words, the layer 10 promotes a current of photogenerated electrons while limiting a current of holes of the substrate 1 to the n− or n+-doped microcrystalline or amorphous silicon layer 5.

The recombinations on the side of the second face of the cell are thereby limited.

Indeed, since it is avoided that photogenerated electrons manage to cross the ΔEc barrier (this barrier being canceled out by the GaN layer), the recombination risk is minimized in the substrate, in the vicinity of the second face, of these electrons with holes which have not crossed the barrier ΔEv.

Simultaneously, since it is avoided that the holes cross the barrier ΔEv (this barrier being increased by the GaN layer), the risk of recombination in the amorphous or microcrystalline silicon layer 5 is minimized, of the holes crossing this barrier with photogenerated electrons having crossed the barrier ΔEc.

Thus, the GaN layer 10 has the effect of minimizing the recombinations both in the substrate 1, in the vicinity of the rear face, and in the amorphous or microcrystalline silicon layer 5 doped with the same type of dopant as the substrate.

Although GaN is the preferred material for the layer 10, it is obvious that one skilled in the art may select any other crystalline semi-conducting material having the required properties, i.e. a conduction band substantially aligned with that of silicon and a forbidden band greater than that of silicon.

Thus, for example, as this is seen in FIG. 5, gallium and indium nitride comprising a small proportion of indium (typically, with a content x of less than 0.2, preferably less than 0.1 in the compound of formula InₓGa₁₋ₓN) may also be suitable for the invention.

It will be noted that the layer 10 does not need to be doped since its conduction band is aligned with that of silicon. It is however possible to dope the layer 10 with doping of the same type as that of the adjacent amorphous or microcrystalline silicon layer 5, i.e. of type n in this embodiment. For example, doping of the donor type of silicon at 10¹⁵ atoms/cm³ may be implemented.

Moreover, the invention is not limited to the case when the substrate is of type n.

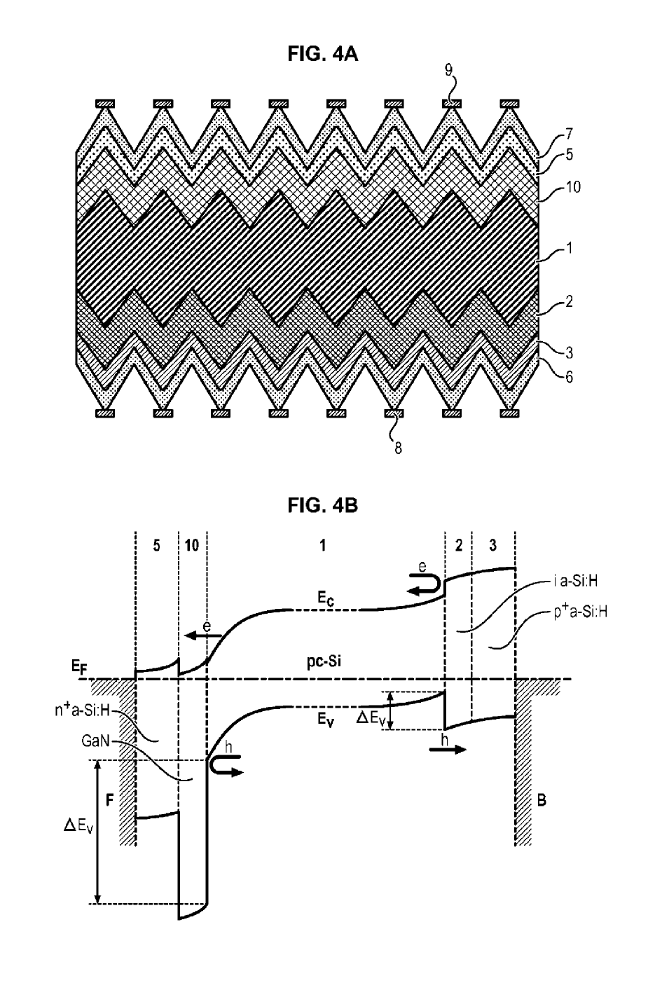

FIG. 4A thus illustrates a cell according to an embodiment of the invention in which the substrate is in p type silicon.

It is considered in this embodiment that the heterojunction is laid out on the front face of the cell, but it is obvious that the invention also applies to a heterojunction placed on the rear face of the cell.

On a first face, the substrate 1 is successively covered with an n− or n+-type doped amorphous or microcrystalline silicon layer 5 or with a layer 7 of a transparent conductive material.

The heterojunction is therefore made on the side of this first face.

On its second face, opposite to the first, the substrate 1 is successively covered with a passivation layer 2, a p− or p+-type doped amorphous or microcrystalline silicon layer 3 and with a layer 6 of a transparent conductive material.

A repulsive field is therefore formed by the layer 3 which is doped with the same type of dopant as the substrate.

The cell further comprises on the first face, between the substrate 1 and the n− or n+-type doped amorphous or microcrystalline silicon layer 5, a layer 10 of a crystalline semi-conducting material having a conduction band substantially aligned with the conduction band of silicon and a forbidden band greater than that of silicon.

In a particularly advantageous way, the material of the layer 10 is gallium nitride.

Indeed, as explained above with reference to FIG. 5, GaN has a conduction band substantially aligned with that of silicon and a forbidden band of 3.4 eV, which is clearly greater than that of silicon, which is of the order of 1.1 eV.

The effect of this GaN layer 10 is illustrated in FIG. 4B, which illustrates the band diagram of a photovoltaic cell with a heterojunction as schematized in FIG. 4A.

At the interface between the type p silicon substrate 1 and the GaN layer 10, the shift ΔEc of the conduction bands is zero since the conduction bands of both of these materials are substantially aligned.

On the other hand, because of the greater forbidden band of GaN, the shift ΔEv of the valence bands is greater than in the absence of the GaN layer (FIG. 2B) and is of the order of 2.3 eV.

The result of this layout of the bands is that the photogenerated electrons no longer encounter any barrier opposing their passage towards the n− or n+-doped amorphous or microcrystalline silicon layer 5.

On the other hand, the holes encounter a high barrier which opposes their passage towards the layer 5.

In other words, the layer 10 promotes a current of photogenerated electrons while limiting a current of holes from the substrate 1 to the n− or n+-doped amorphous or microcrystalline silicon layer 5.

The recombinations on the side of the first face of the cell are thereby limited.

Indeed, since it is avoided that photogenerated electrons manage to cross the barrier ΔEc (this barrier being canceled out by the GaN layer), the recombination risk in this substrate in the vicinity of the first face of these electrons with holes not having crossed the barrier ΔEv is minimized.

Simultaneously, since it is avoided that holes cross the barrier ΔEv (this barrier being increased by the GaN layer), the recombination risk, in the amorphous or microcrystalline silicon layer 5, of the holes crossing this barrier with photogenerated electrons having crossed the barrier ΔEc is minimized.

Thus, the GaN layer 10 has the effect of minimizing the recombinations both in the substrate 1, in the vicinity of the rear face, and in the amorphous or microcrystalline silicon layer 5 doped with the same type of dopant as the substrate.

As indicated for the previous embodiment, GaN is the preferred material for the layer 10 but one skilled in the art may select another crystalline semi-conducting material (for example gallium and indium nitride with a small proportion of indium) having the required properties, i.e. a conduction band substantially aligned with that of silicon and a forbidden band greater than that of silicon, without however departing from the scope of the invention.

Moreover, as already indicated for the previous embodiment, the layer 10 does not need to be doped since its conduction band is aligned with that of silicon. However it is possible to dope the layer 10 with doping of the same type as that of the adjacent amorphous or microcrystalline silicon layer 5, i.e. of type p in this embodiment. For example, an acceptor type doping at 10¹⁵ atoms/cm³ may be implemented.

The inventors have checked the effect of the insertion of the crystalline semi-conducting material on the properties of the cell by means of numerical simulations using the software package Atlas Silvaco.

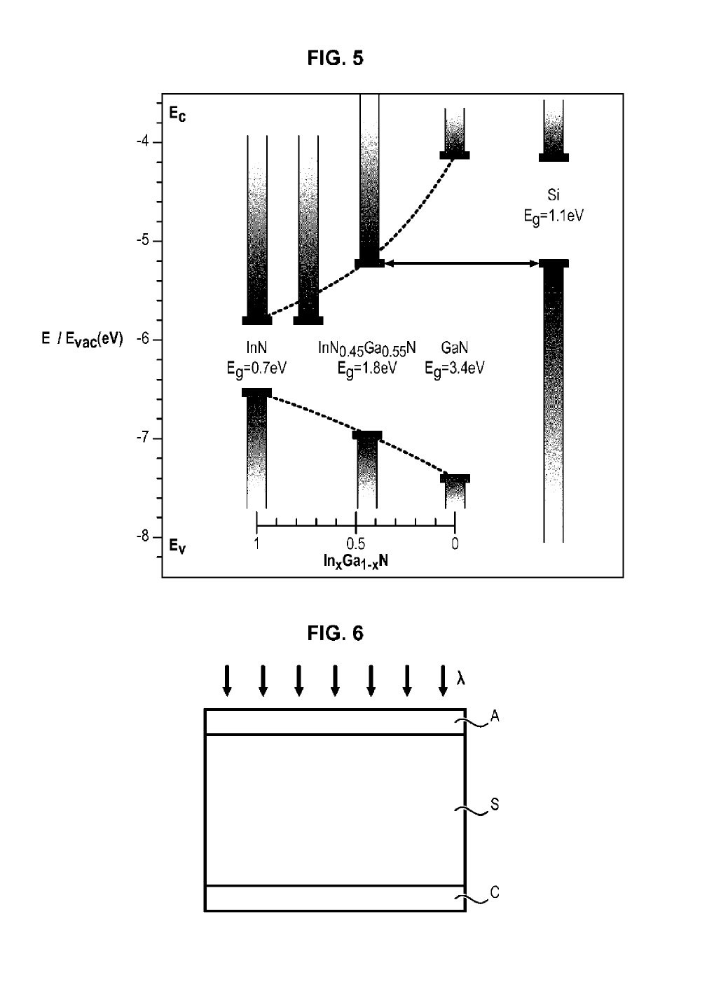

FIG. 6 shows the simulated structure and the simulated incident radiation (λ=600 nm), uniformly applied on the front face of the structure.

This structure comprises a substrate S of n-doped crystalline silicon (10¹⁵ cm⁻³), on the front face of an anode A consisting of a p+-doped amorphous silicon layer (5×10¹⁹ cm⁻³) and on the rear face a cathode C consisting of a layer of crystalline semi-conducting material for which the width of the forbidden band has been varied.

Indeed, in order to demonstrate the effect of the width of the forbidden band of the layer 10 on the current characteristic of the cell, two similar structures were simulated:
the first structure was simulated with a layer forming the cathode having a forbidden band of 1.58 eV;
the second structure was simulated with the layer forming the cathode having a forbidden band of 3.4 eV, corresponding to the n-doped GaN layer (10¹⁵ cm⁻³).

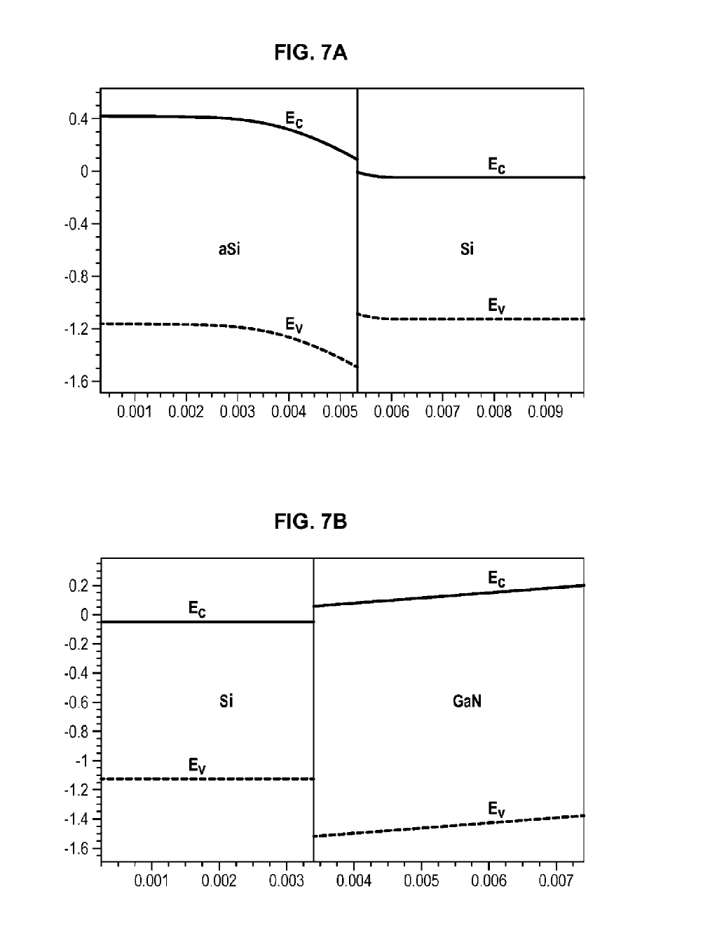

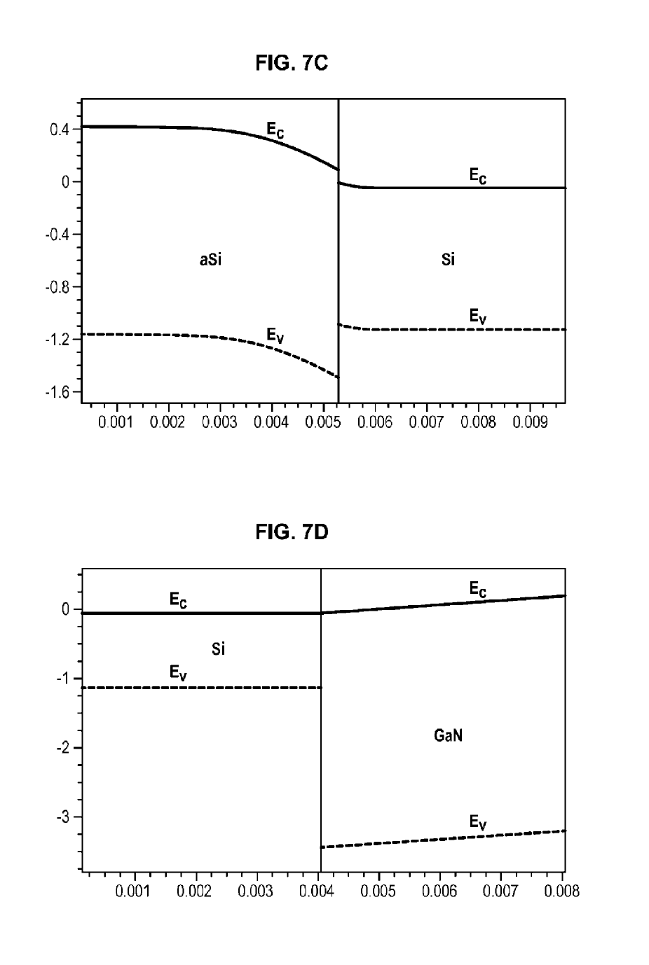

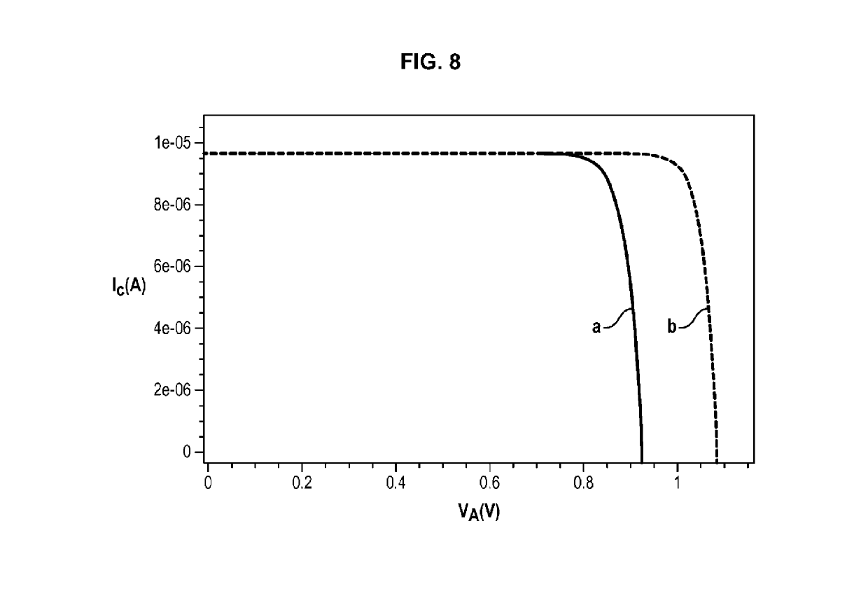

FIGS. 7A and 7B respectively illustrate the band diagrams of the first simulated structure, at the anode and at the cathode; FIGS. 7C and 7D respectively illustrate the band diagrams of the second simulated structure, at the anode and at the cathode.

FIG. 8 shows the variation of the cathode current Ic versus the bias at the anode V_{A} for the first structure (curve a) and for the second structure (curve b).

The comparison of curves a and b show that the short-circuit voltage is greater for the second structure than for the first structure, with the same open circuit current.

This characteristic shows that the power potentially delivered by the second structure is greater than that of the first structure.

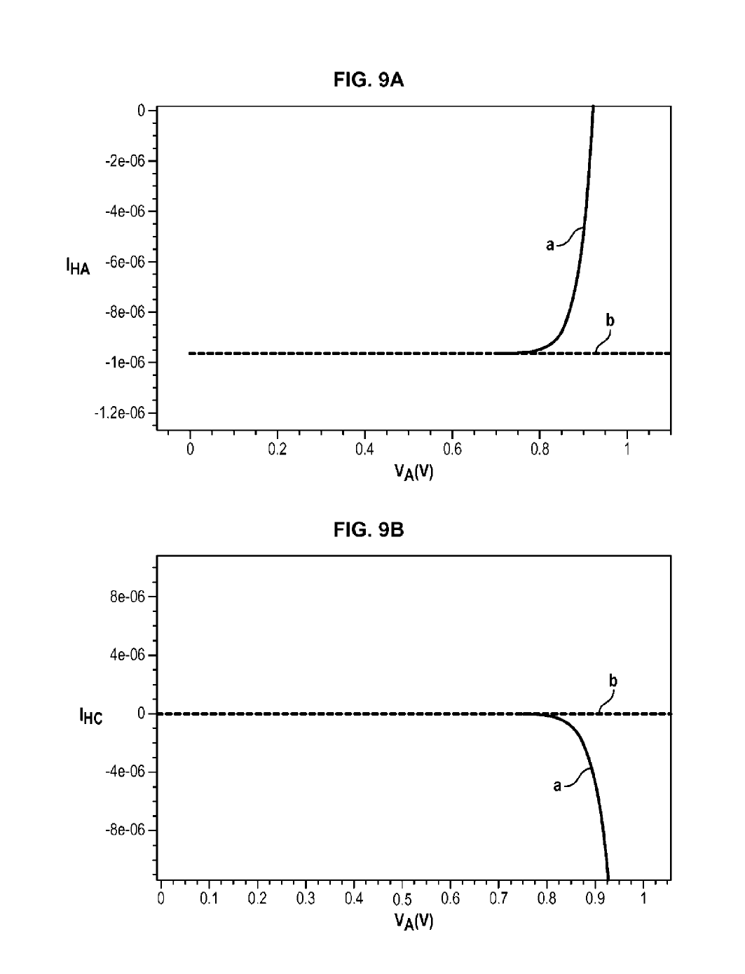

FIG. 9A shows the variation of the hole current at the anode I_{HA} versus the bias at the anode V_{A} for the first structure (curve a) and for the second structure (curve b).

This figure shows a hole current at the anode equal or greater for the second structure than for the first.

FIG. 9B shows the variation of the hole current at the cathode I_{HC} versus the bias at the anode V_{A} for the first structure (curve a) and for the second structure (curve b).

This figure shows a hole current at the cathode equal to zero for the second structure and non-zero for the first structure, which shows that the band structure of GaN (second structure) gives the possibility of better blocking the passage of the holes to the cathode than a material with a forbidden band of a smaller width (1.58 eV for the first structure).

Therefore, the GaN layer of the second structure, with a forbidden band of 3.4 eV, gives the possibility of obtaining a higher power than with a layer of a material having a forbidden band of 1.58 eV.

A method for manufacturing the cells described above will now be described.

A substrate 1 of silicon of type n or p is provided.

According to a particularly advantageous embodiment, when the material of the layer 10 is GaN, the face of the substrate intended to be covered with said GaN layer is textured so as to form on this face, pyramids revealing the planes (111) of the silicon.

Indeed, the triangular geometry of such a texture has three axes of symmetry in common with the planes of GaN, the structure of which is hexagonal.

Texturation techniques are known per se and will therefore not be described in detail here.

Texturation in random pyramids with chemistry of the KOH (potassium hydroxide) type may for example be carried out.

The layer 10 is then formed by epitaxy on one face of the substrate 1.

The epitaxy gives the possibility of forming a crystalline layer 10, which is optimum for the quality of the interfaces.

In the case of GaN, the layer 10 may be formed by molecular beam epitaxy (MBE, or by metal organic vapor phase epitaxy (MOVPE), at a temperature preferably comprised between 600 and 800° C.

The thickness of the layer 10 may be comprised between 0.5 nm and 50 nm, preferably between 1 nm and 10 nm.

The remainder of the cell is then formed in a conventional way.

In a way known per se, producing the stack of the passivation layer, of the amorphous or microcrystalline silicon layer and of the transparent conductive material typically comprises the following steps:
on the epitaxial layer 10, deposition of the n− or n+-type doped amorphous or microcrystalline silicon layer 5. This deposition may be achieved with PECVD (Plasma-Enhanced Chemical Vapor Deposition). The thickness of the layer 5 is typically comprised between 4 and 40 nm.
on the opposite face, deposition on the substrate 1 of a passivation layer 2 for example in amorphous silicon. This deposition may be carried out with PECVD. The thickness of said layer is typically comprised between 0.5 and 20 nm.
deposition on said passivation layer 2, of a p− or p+-type doped amorphous or microcrystalline silicon layer 3. This deposition may also be carried out with PECVD. The thickness of said layer is typically comprised between 4 and 40 nm.
on each of the faces, deposition of the layers 6 and 7 of a transparent conductive material, for example ITO. This deposition may be carried out with PVD (Physical Vapor Deposition). The thickness of the layers 6 and 7 is typically comprised between 50 and 150 nm.
making collectors 8 and 9 by metallization of the front face and of the rear face respectively, for example by screen printing.

### REFERENCES

[Kinoshita11]T. Kinoshita, D. Fujishima, A. Yano, A. Ogane, S. Tohoda, K. Matsuyama, Y. Nakamura, N. Tokuoka, H. Kanno, H. Sakata, M. Taguchi, E. Maruyama, The approaches for high efficiency HIT™ solar cell with very thin (<100 μm) silicon wafer over 23%, Proc. of 26th European Photovoltaic Solar Energy Conference and Exhibition, 2011
[Hekmatshoar11] Bahman Hekmatshoar, Davood Shahrjerdi, Devendra K. Sadana, Novel Heterojunction Solar Cells with Conversion Efficiencies Approaching 21% on p-Type Crystalline Silicon Substrates, Proc. of IEDM 2011.
[Ager09] Joel W. Ager, Lothar A. Reichertz, Yi Cui, Yaroslav E. Romanyuk, Daniel Kreier, Stephen R. Leone, Kin Man Yu, William J. Schaff, Wladyslaw Walukiewicz, Electrical properties of InGaN—Si heterojunctions, Phys. Status Solidi C 6, No. S2, S413-S416 (2009)

1. A photovoltaic cell with a silicon heterojunction, comprising an n- or p-type doped crystalline silicon substrate, wherein:
a first main face of the substrate is successively covered with a passivation layer, with a p− or p+-type doped amorphous or microcrystalline silicon layer and a layer of a transparent conductive material,
the second main face of the substrate is successively covered with a layer of n− or n+-type doped amorphous or microcrystalline silicon and with a layer of a transparent conductive material,
said cell further comprising, between the substrate and the n− or n+-type doped amorphous or microcrystalline silicon layer, a layer of a crystalline semi-conducting material selected from among gallium nitride and gallium and indium nitride and having a conduction band substantially aligned with the conduction band of silicon and a forbidden band greater than that of silicon, so that said crystalline semi-conducting material layer promotes a current of electrons while limiting a current of holes from the substrate to the n− or n+-type doped amorphous or microcrystalline silicon layer.

2. The cell according to claim 1, wherein the second main face of the substrate has a texture revealing the planes (111) of the silicon.

3. The cell according to claim 1, wherein the thickness of the layer of said crystalline semi-conducting material is comprised between 0.5 nm and 50 nm, preferably between 1 nm and 10 nm.

4. A method for manufacturing a photovoltaic cell with a silicon heterojunction comprising:
forming successively, on a first main face of a substrate of n- or p-doped crystalline silicon, a passivation layer, a p− or p+-type doped amorphous or microcrystalline silicon layer, a layer of a transparent conductive material and a first collector of carriers,
forming successively, on the second main face of the substrate, an n− or n+-type doped amorphous or microcrystalline silicon layer, a layer of a transparent conductive material and a second collector of carriers,
said method further comprising, before forming said n− or n+-type doped amorphous or microcrystalline silicon layer, forming, by epitaxy on the substrate, a layer of a semi-conducting material selected from gallium nitride or gallium and indium nitride and having a conduction band substantially aligned with the conduction band of silicon and a forbidden band greater than that of silicon.

5. The method according to claim 4, wherein the second face of the substrate is textured beforehand so as to form pyramids revealing the planes (111) of the silicon.

6. The method according to claim 4, wherein the crystalline semi-conducting material is gallium nitride and the gallium nitride layer is formed by molecular beam epitaxy (MBE) or by metal organic vapor phase epitaxy (MOVPE).

7. The method according to claim 6, wherein the epitaxy temperature of said gallium nitride layer is comprised between 600 and 800° C.

8. The method according to claim 4, wherein the thickness of the layer of semi-conducting crystalline material is comprised between 0.5 nm and 50 nm, preferably between 1 nm and 10 nm.
